(19) United States
(12) Patent Application Publication
(10) Pub. No.: US 2018/0267425 A1
(43) Pub. Date: Sep. 20, 2018

(54) METHOD FOR IMPROVED CD CONTROL ON 2-PHASE DIGITAL SCANNER WITH NO LOSS TO IMAGE FIDELITY

(71) Applicant: Nikon Corporation, Tokyo (JP)

(72) Inventor: Shane R. Palmer, Oro Valley, AZ (US)

(73) Assignee: Nikon Corporation, Tokyo (JP)

(21) Appl. No.: 15/917,522

(22) Filed: Mar. 9, 2018

Related U.S. Application Data
(62) Division of application No. 14/617,863, filed on Feb. 9, 2015, now abandoned.
(60) Provisional application No. 61/937,395, filed on Feb. 7, 2014.

(51) Int. Cl. G03G 15/043; G03F 7/20

(52) U.S. Cl. CPC G03G 15/043; G03F 7/70291; G03F 7/7055; G03F 7/70558; G03F 7/2057

(57) ABSTRACT

Patterns from a phase array are transferred to a substrate such as a series of overlapping patterns and non-overlapping patterns. The overlapping patterns are associated with phase array pixel offsets so as to overlap at the substrate and the necessary overlap is based on substrate scan speed. Non-overlapping or offset patterns are obtained by varying optical pulse timing as the substrate is scanned, or by including a corresponding offset to pattern definition at the phase array.

### CROSS REFERENCE TO RELATED APPLICATIONS

This application is a divisional of U.S. application Ser. No. 14/617,863, filed Feb. 9, 2015, which claims the benefit of U.S. Provisional Application No. 61/937,395, filed Feb. 7, 2014, both of which are incorporated herein by reference.

### FIELD

The disclosure pertains to pattern transfer using digital scan patterns.

### BACKGROUND

Binary mirror arrays can be used to transfer patterns to sensitized substrates. In some cases, pixels can be arranged to provide different intensities so that, for example, exposure intensity at pattern edges can be controlled. Unfortunately, adjusting intensity in this manner is associated with a loss in resolution, and is therefore unacceptable in many applications.

### SUMMARY

In one example, methods can provide critical dimension (CD) control for images printed with a two-phase digital scanner without loss of image fidelity or with reduced loss of image fidelity using a double-pulse shift to the incident illumination for a selected set of pixels or using a twin local pixel shift to local patterns.

In some examples, exposure methods for transferring a pattern to a substrate comprise exposing the substrate to a plurality of phase patterns defined by a phase array having a plurality of phase elements such that the patterns overlap on a selected substrate area. The substrate is further exposed to a plurality of phase patterns such that the patterns are offset with respect to the plurality of overlapping patterns. The offset is obtained by adjusting one or more exposure times or by shifting the phase pattern at the phase array so as to be offset. In some examples, the substrate is exposed such that the pattern overlap is based on a series of optical pulses, such that for each optical pulse the substrate is scanned and the phase pattern on the substrate is shifted. In other examples, the phase pattern shift is based on application times of the series of optical pulses and the substrate scan speed.

An exposure method for transferring a pattern to a substrate comprises exposing the substrate to a plurality of phase patterns defined by a phase array having a plurality of phase elements such that the phase patterns overlap on a selected substrate area. The substrate is also exposed to a plurality of phase patterns such that the patterns are offset with respect to the plurality of overlapping patterns, wherein the offset is obtained by adjusting one or more exposure times or by shifting the phase pattern at the phase array so as to be offset. In some examples, a zero mosaic pattern is associated with a selected pattern portion and exposure. According to some examples, the exposure to the offset phase patterns is performed before or after exposure to the overlapping phase patterns, the exposures to the offset phase patterns is performed in part before and in part after exposure to the overlapping phase patterns. Typically, a total number of exposures and a number of offset pattern exposures is based on a selected photoresist.

Exposure apparatus comprise an optical pulse source and a programmable phase array containing a plurality of phase elements, the programmable phase array situated to be irradiated by the optical pulse source. An optical system directs an image of the programmable phase array to a substrate and a phase array controller establishes a phase pattern offset at the substrate based on one or more of an optical pulse rate, a substrate scan speed, a phase element length or width, such that the substrate is exposed to a series of overlapping patterns and a series of offset patterns. In some examples, the programmable phase array includes a primary phase array and a secondary phase array, wherein the primary phase array and the secondary phase array are coupled to apply exposures associated with the overlapping phase patterns and the offset phase patterns, respectively. Typically, the overlapping phase patterns are applied by translating the substrate with a substrate stage and making corresponding pattern shift on the phase array.

Methods comprise, in a pattern-transfer system, receiving a pattern to be transferred to a substrate and defining a set of overlapping pattern exposures corresponding to the pattern to be transferred. At least one portion of the pattern to be transferred is selected for exposure compensation, at least one dither exposure pattern is associated with the selected portion of the pattern. In some examples, the defined set of overlapping pattern exposures includes exposure phases for a plurality of pixel exposures or a number of exposures for primary pattern transfer associated with the set of overlapping pattern exposures and a number of dither exposures for the dither exposure pattern are selected. According to representative examples, the numbers of exposures of at least one of the primary pattern and the dither pattern are selected based on a preferred critical dimension.

Apparatus comprise a communication interface and a processor that receives a definition of a pattern to be transferred to a substrate via the communication interface. The processor assigns a number of primary and secondary exposures for a plurality of pattern areas based on a selected critical dimension. The primary exposures for each of the pattern areas are overlapping exposures, and the secondary exposures for each of the pattern areas are offset exposures. A memory is coupled to the processor and stores the assigned numbers of exposures. In some examples, the processor assigns an offset for each of secondary exposures, and the offsets for some or all such exposure s can be the same or different.

The foregoing and other objects, features, and advantages of the disclosure will become more apparent from the following detailed description, which proceeds with reference to the accompanying figures.

### BRIEF DESCRIPTION OF THE DRAWINGS

FIG. 1A is a block diagram of a pattern transfer apparatus that transfers patterns from a programmable phase mask to scanned substrate using dithered exposures.

FIG. 1B is a block diagram of a pattern transfer apparatus that transfers patterns from a programmable phase mask to scanned substrate using primary and secondary programmable pixel arrays.

FIGS. 2A-2B illustrate pattern transfer without dithering.

FIG. 3 illustrate edge effects in undithered exposures.

FIG. 4 illustrates an exposure method using time-dithered exposures based on varying exposure pulse timing.

FIGS. 5A-5B illustrate pattern transfer using the method of FIG. 4.

FIG. 6 illustrates a pattern-transfer method using pixel offsets defined by a programmable phase mirror or other programmable phase device.

FIG. 7 illustrates a resultant latent image at a wafer produced by a pixel array after N shots. The center graph shows a horizontal cross section of the images through ± defocus and the right plot has the resultant summation of the defocussed images divided by the number of defocus images Nf. The defocus range is selected to provide an estimate of typical edge roughness.

FIG. 8 illustrates negative CD dithering achieved by using the exposure below the nominal (100%) value and then adding “dithered” exposures.

FIG. 9 illustrates of positive dithering to achieve a 38.5 nm target space from the nominal 35 nm space with a digital 2-phase scanner.

FIG. 10 shows a range of dithering achieved using 20 dither flashes to a 35 nm nominal space feature at 160 nm pitch. Note that the center points at nominal do not line up due to the 10 “dropped” flashes (to allow for negative dithering).

FIG. 11 illustrated results obtained for various dither combinations.

FIG. 12 is a process-flow diagram depicting exemplary steps associated with a processing a substrate (e.g., a wafer) using dithered exposures.

FIG. 13 illustrates a representative computing environment for determining primary and secondary (dithered) exposures.

### DETAILED DESCRIPTION

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or apparatus' are referred to as “lowest”, “best”, “minimum,” or the like. It will be appreciated that such descriptions are intended to indicate that a selection among many used functional alternatives can be made, and such selections need not be better, smaller, or otherwise preferable to other selections.

Multiple exposure sequences are noted as, for example, “N360+2N5ss10,” indicating 360 exposures without offset (undithered exposures) and 2 sets of 5 exposures symmetrically offset by 10 nm. Other values of undithered and dithered exposures can be used, with symmetric or asymmetric dithers (or one-sided dithers) of the same or different effective distances on a substrate. The evaluations described herein are based on simulations using appropriate photoresist characteristics.

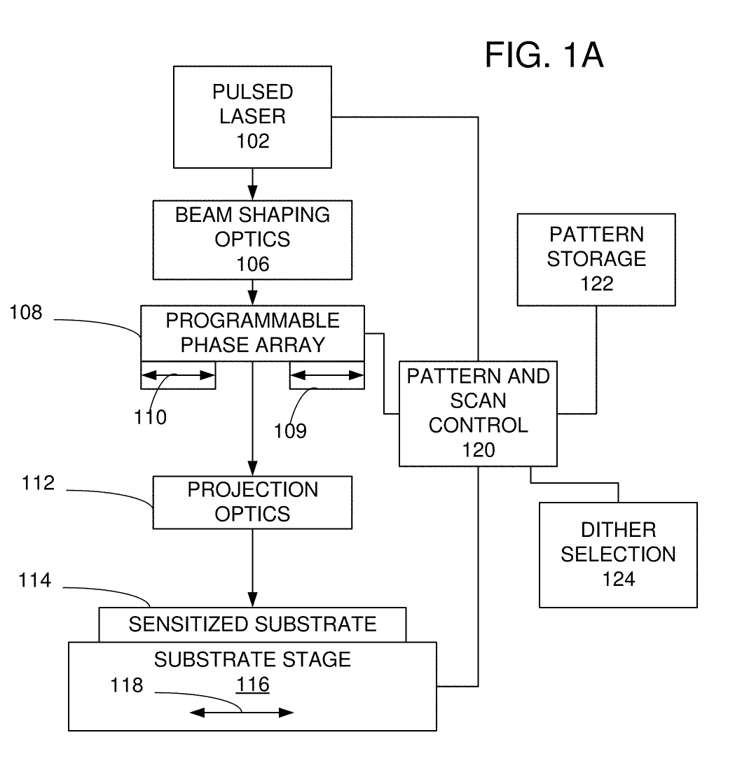

As shown in FIG. 1A, an exposure apparatus 100 includes a pulsed light source such as pulsed laser 102 that directs an optical beam to beam shaping optics 106 that process the optical beam and direct the optical beam to a programmable phase array 108 that is secured to a pattern stage 109 that can move the programmable phase array 108 along one or more axes, such as axis 110. For convenience, the phase array 108 is also referred to herein as a phase-shift pixelated mask. An optical beam modulated by the programmable phase array 108 is received by projection optics 112 that directs a patterned beam to a sensitized substrate 114 that is coupled to a substrate stage 116 that can move the sensitized substrate along one or more axes, such as axis 118. A controller 120 receives and/or processes pattern data from a pattern storage device 122 and controls the positions of the programmable phase array 108, the sensitized substrate 114, and laser pulse timing (such as pulse repetition rate). In addition, the controller 120 is coupled to the programmable phase array 108 so as to establish pixel phases based on patterns from the pattern storage device 122. In some examples, the programmable phase array 108 is a rectangular array of phase pixels, each pixel of which is typically assigned one of two values, such as 0 phase shift or ½ wave phase shift or some other combination. Multiple phase levels can be used, if desired. The laser source 102 produces an optical beam at a suitable wavelength or wavelength range for exposure of a sensitized layer of the sensitized substrate 114.

The arrangement of FIG. 1A is shown with a transmissive programmable phase array and refractive optical elements, but reflective programmable phase arrays and/or reflective optical systems can be used, and are especially convenient for exposures at wavelengths below 200 nm, such as 193 nm. Additional beam forming and beam directing optical elements can be used such as mirrors and prisms that fold or bend an optical path, but are omitted for clarity in FIG. 1A. Sensitized substrates generally include a semiconductor wafer or other material to which a photosensitive layer has been applied for used in photo-patterning.

Using an apparatus such as that of FIG. 1A, the sensitized substrate 114 is moved with respect to a projected image of a pixelated phase pattern based on a pattern establishing by the programmable phase array 108. A final compound pattern at the sensitized substrate 114 is created by projecting the image that is obtained from the programmable phase array 108 in a series of overlapping exposures (exposure shots) corresponding to different laser pulses or sets of laser pulses. The overlapping exposures of the pattern of the programmable phase array 108 are temporally spaced based on a laser pulse repetition rate (for fixed frequency exposures). Between each laser pulse, the sensitized substrate 114 is moved a distance corresponding to a product of a time between laser pulses and a speed of the substrate stage 116. To maintain pattern registration, the pattern defined by the programmable phase array 108 is also shifted from pulse to pulse or otherwise so as to maintain intended exposure on the sensitized substrate 114. For example, if substrate scanning produces a displacement corresponding to a single phase element of the programmable phase array 108 between each pulse, the pattern on the programmable phase array 108 is shifted by one pixel between each pulse. Periodic pulses are not required, and other pulse sequences can be used, with corresponding displacement(s) of the pattern defined by the programmable phase array 108. A final pattern on the sensitized substrate is produced by the combination of exposures from many pulses and associated with a series of displaced phase patterns at the programmable phase array 108.

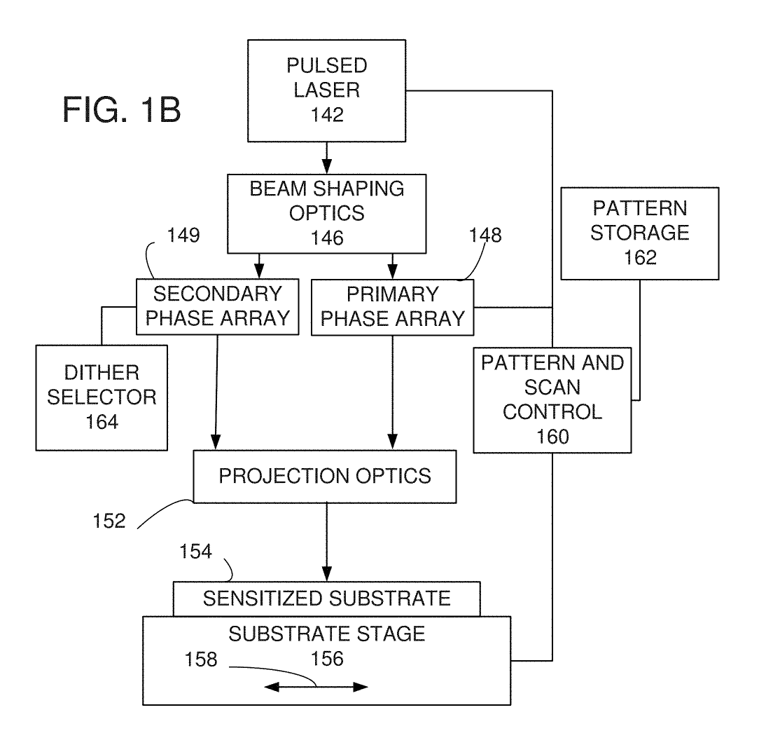

An example of the creation of a pattern by substrate scanning and exposure with a programmable phase array is shown in FIG. 2A which shows projected patterns from a series of pulse exposure (“flashes”). As shown in FIG. 2A, a pattern moves from left to right for each flash, and the substrate is scanned a corresponding distance so that the flashes remain aligned on the substrate. Flash 1 contains only a small pattern defined by the phase array, typically including at least in part, a checkerboard pattern of zero- and π-phase pixels. At the time of the Flash 2, the substrate has been moved a distance d under the stationary phase pattern that is equal to the product of stage speed and interflash time, i.e., d=v(t₂−t₁). The wafer has thus been exposed to the pattern of Flash 1 and the translated pattern of Flash 1, producing two exposures of the pattern portion of Flash 1 and additional pattern portions introduced by Flash 2. This process is repeated until the entire pattern is completed. Any given feature on the substrate is comprised of the sum of many exposures. FIG. 2B shows a final pattern exposure corresponding to a sum of the prior flashes. Typically, the programmable phase array is stationary and the substrate is translated. The pattern on the programmable phase array is changed with each successive flash to account for the movement by the substrate stage and is shifted by a distance d divided by the phase pixel size. For example, for a substrate stage that is moving at 0.8 m/s, a laser PRF=2 MHz, and a pixel dimension dₚ in a scan direction of 20 nm, the pixel or pattern shift per pulse is

PSP=v/(PRF·dₚ)=20 pixels.

In typical exposures, total exposure at each point on the substrate is a result of the summation of fixed number of flashes N. N can be determined from the length of the programmable phase array divided by the PSP. For example, with a pixel array that contains 800×10³ pixels (in the direction of the stage motion), N=400.

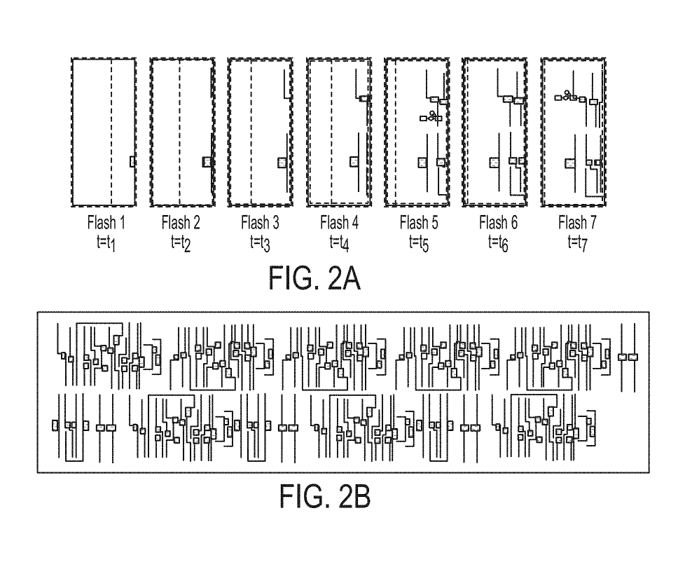

In general, the final pattern created on a substrate from the N exposures is pre-optimized to print at a critical dimension (CD). This exposure level is called the nominal exposure, or best exposure to achieve the dimension of the critical target. However, features that differ in dimension from the critical target can have errors as a result of the non-optimal exposure and size. This is also a result of the finite pixel size of the phase array. The highest fidelity pattern that can be printed with a phase-shift pixelated mask occurs when feature edges have a minimum number of transitions between zero- and π-phase shifted pixels along that edge. However, in a static mode, e.g. with a fixed pixelation, a feature edge can only be moved by changing the phase of the pixels along that edge, resulting in increased blur or spread of the image. Image blur and image spread result in the loss of CD control and translate to line-edge roughness or LER. An example to illustrate the increase of blur and line edge roughness for features sizes that differ from the nominal (0 nm) is shown in FIG. 3. Note the change of the pixel patterns (top) used to define the edge of the non-nominal line and space patterns (below).

In an alternative arrangement shown in FIG. 1B, an exposure apparatus 140 includes a pulsed light source such as pulsed laser 142 that directs an optical beam to beam shaping optics 144 that process the optical beam and direct the optical beam to a primary programmable phase array 148 that is secured to a pattern stage that can move the primary programmable phase array 148 along one or more axes. A secondary programmable phase array 149 is situated to receive the optical beam as well. An optical beam modulated by the programmable phase arrays 148, 149 is received by projection optics 152 that directs a patterned beam to a sensitized substrate 114 that is coupled to a substrate stage 156 that can move the sensitized substrate along one or more axes, such as axis 158. A controller 160 receives and/or processes pattern data from a pattern storage device 162 and controls the positions of the programmable phase arrays 148, 149, the sensitized substrate 164, laser pulse timing (such as pulse repetition rate). In addition, the controller 160 is coupled to the primary programmable phase array 148 so as to establish pixel phases based on patterns from the pattern storage device 162. In some examples, the primary programmable phase array 148 is a rectangular array of phase pixels, each pixel of which is typically assigned one of two values, such as 0 phase shift or ½ wave phase shift or some other combination. The secondary phase array can be a linear or two-dimensional pixel array and is coupled to a dither selector 164 so as to provide suitable exposure compensation as discussed above. The secondary array 149 can be situated to apply compensation before or after exposure by the primary array 148. The laser source 102 produces an optical beam at a suitable wavelength or wavelength range for exposure of a sensitized layer of the sensitized substrate 114.

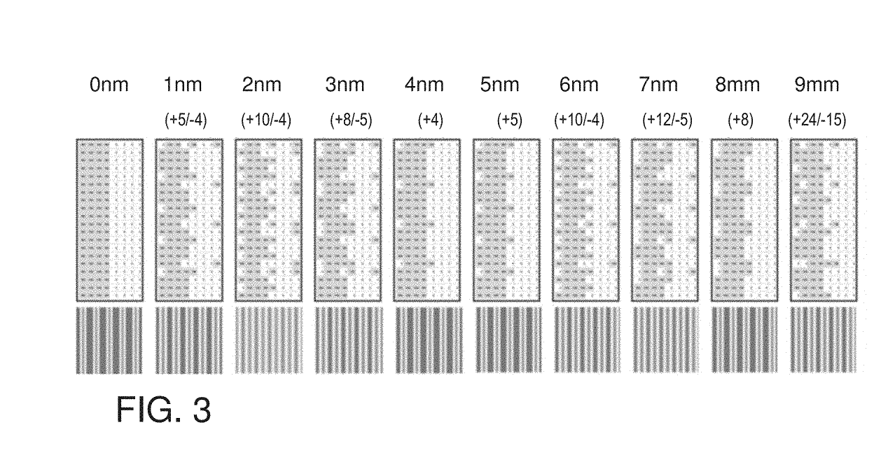

Referring to FIG. 4, a method 400 that can achieve a non-nominal CD without introducing large image blur includes selecting a nominal critical dose N−Nd at 402, wherein Nd is a number of dither shots. The number of dither shots Nd can be determined based on a number of flashes/exposures required to produce a non-nominal CDs (i.e., variation of the edges from nominal) at 403. At 404, a two-step time shift is selected for the exposure source. The shift is determined by the pattern to be exposed, but generally does not exceed 1 pixel divided by the stage speed. Time shift is referred to herein as a dither as it represents generally small offset from a nominal pulse interval. At 406, the substrate is exposed with selected numbers of dithered and undithered pulses. In one example, a nominal 400 flashes per feature are used to scan with a phase mask (32 k X-pixels by 8 k Y-pixels with a 20 nm pixel) with a wafer speed of 0.8 m/sec. A fraction (5%-10%) of the total flashes are used in dithering, typically selected to obtain a maximum CD change at ½ pixel delay. In this example, a 1.25 ns pulse delay variation corresponds to 1 nm of dither offset at the wafer, and corresponds to 0.375 m change in pulse path length in air. Typically, weighted symmetric time (or position) shifted nominal images are added to a baseline image, keeping proper normalization to total, i.e., ΣIₒ/Nₒ+ΣIₙ(t)/Nₙ, wherein Iₒ refers to single exposure intensity for Nₒ undithered exposures and Iₙ(t) refers to exposure intensity for Nₙ temporally dithered exposures.

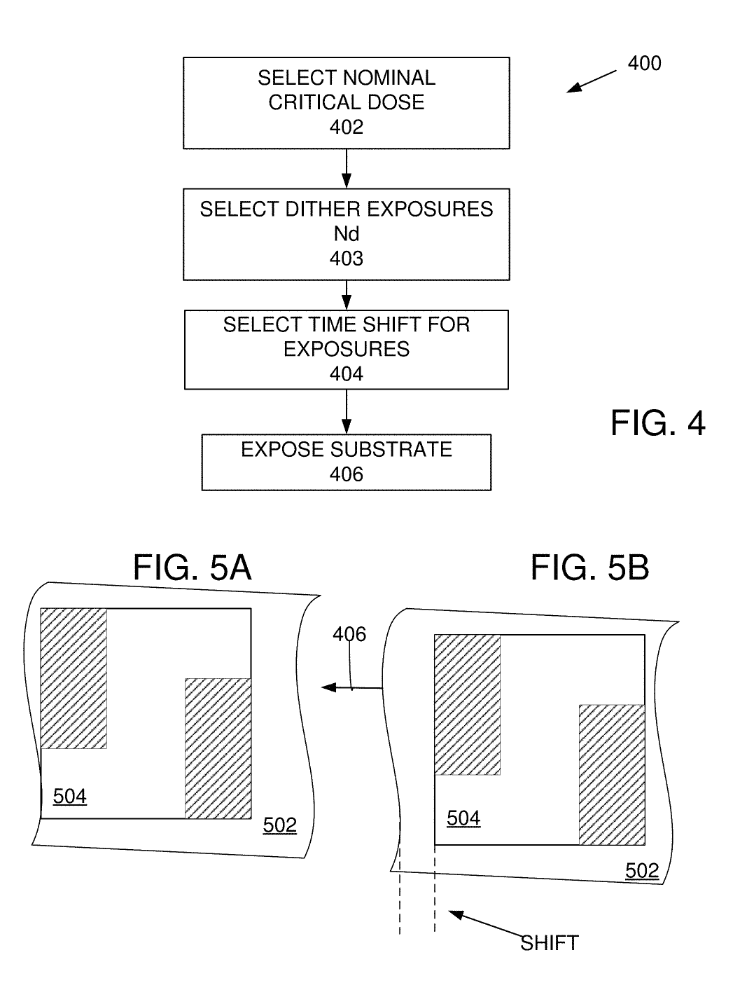

FIGS. 5A-5B illustrate a substrate portion 502 and a pattern portion 504 as projected onto the substrate with dither. A first set of exposures is made with the pattern portion 504 effectively situated with respect to the substrate portion 502 as shown in FIG. 5A such as shown in FIG. 2A. These exposures typically are based on pattern shifts at the programmable phase array so as to compensate for substrate motion in a direction 506. A second set of exposures is made with a pulse timing difference so as to produce an effective pattern shift as shown in FIG. 5B. Multiple shifted exposures similarly are based on compensating for substrate motion. The first and second sets of exposures are not necessarily made sequentially; alternating exposures can be made, or other sequences. Similar exposure results could be obtained with dither of substrate motion, but such mechanical dither is generally impractical.

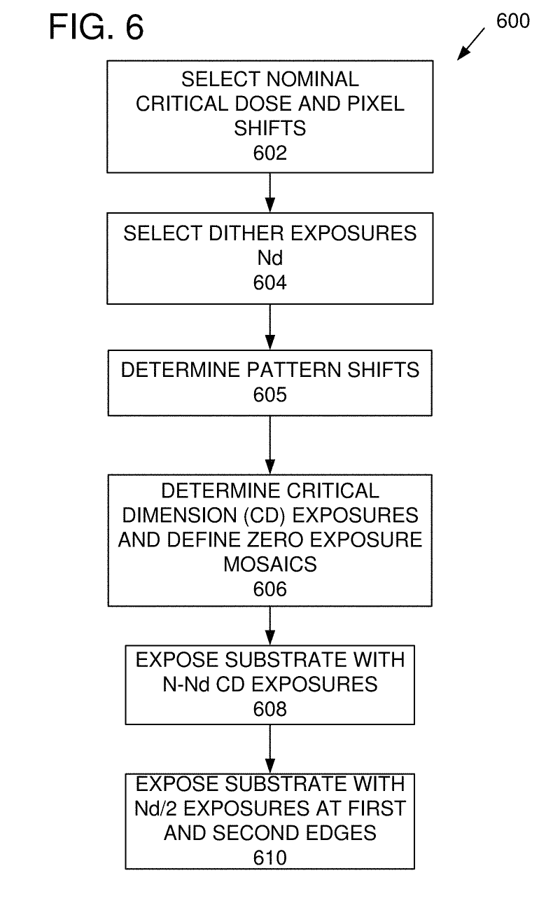

Another approach is illustrated in FIG. 6. At 602, a one or more pixel shifts (such as symmetric or asymmetric pixel shifts, or a uniform double shift) is defined for application to the phase array during exposure. Unlike variations in pulse timing (pulse dither), shift amounts are fixed by the phase array pixel size and may require larger dither numbers. However, using a full pixel shifts does not require changing pulse timing (although pulse timing can be changed as well as described above if desired). In addition, pixel shifts can be used to compensate or correct both Y and X edges (i.e., directions along and perpendicular to a substrate scan direction) in exposed patterns at the substrate. This method also may be used to blend exposures between adjacent fields during pattern writing. A nominal critical dose is also selected. At 604, a number of dither pulses Nd is evaluated in conjunction with selected pixel shifts to provide an intended edge or feature correction. Typically, a smallest number of dither exposures is preferred. At 605, pattern shifts are determined. At 606, a nominal exposure of a critical target pattern feature is set to N−Nd. Exposures of features that are at the critical size (generally sizes that correspond to nearly uniform zero and π phase shift edge transitions) can be made with N−Nd flashes. Exposures made with pre- and post-shifted pulses (Nd/2 each for symmetric shifts) for such features are then avoided by defining a mosaic pattern (alternating 0 and π phase shifts) that produces a low or near zero additional exposure. At 608, N−Nd exposures corresponding to CD features are made. At 610, patterns and pattern features that produce edges that result in larger than an intended CD are printed with a constant “best” array of pixels that produce these features at N−Nd. The final CD value (for selected features) is then produced with Nd/2 dither exposures, and additional exposure of these features is reduced using mosaic patterns for the remaining Nd/2 dither exposures. Thus, some features are printed with N−Nd/2 effective exposures, while others with N exposures. This is referred to as negative dither. Other combinations are possible, with differing numbers of dither exposures, symmetric or asymmetric about x- and/or y-edges. In other examples, patterns that result in CDs less than a desired target at nominal flash count (N) are exposed with a constant best array to produce an exposure with N flashes and then corrected with all Nd dither exposures. Thus, some features are printed with N+Nd/2 effective exposures, while others with N exposures. This can be referred to as positive dither.

Although the dither exposures are described above with reference to being applied first, second, or in other temporal order, a particular temporal ordering is not required, and dithered and undithered exposures or series of exposures can be alternated or otherwise arranged.

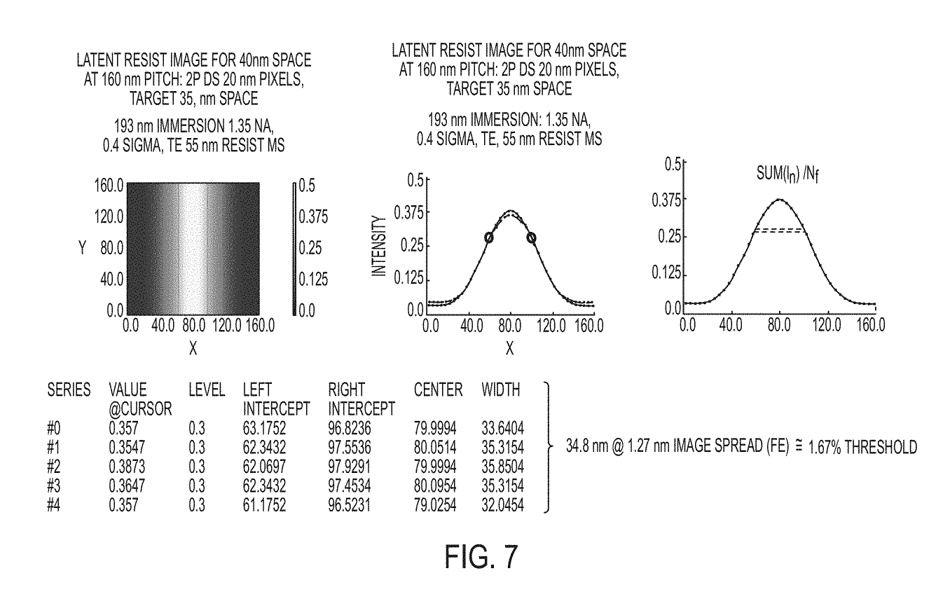

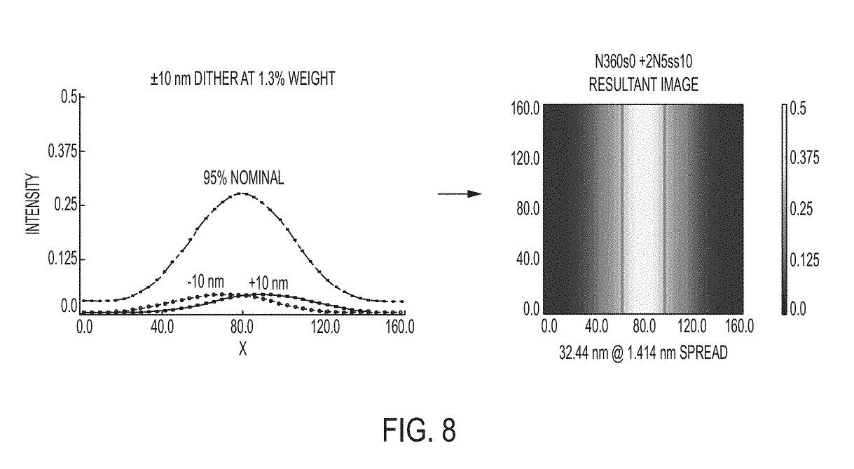

As an example, correction to a 35 nm target space feature at 160 nm pitch using the dithering method is illustrated. FIG. 7 shows a resultant resist latent image that is produced using a nominal exposure. The image spread of the nominal target CD is 1.27 nm in this example with a defocus value of 20 nm. The exposure variation of 1.67% corresponds to this image spread and is determined from the right plot (see dotted lines). A pattern that needs to be printed at 32.5 nm is included along with printed features with CDs at 35 nm. To do this, without significant loss to mage fidelity, a 32 nm space is exposed with a nominal −Nd exposures. Total flash count is set to 400 and a dither of 40 flashes (or 10%) of the total flash count and an offset of 10 nm are introduced, corresponding to a time shift to the pulses of ±12.5 nanoseconds. Results are shown in FIG. 8. The left plot shows the total exposure sequence using 10 dithered pulses (5 negative in time, and 5 forward in time) are added to the 95% (or 360) nominal flashes. Some efficiency is lost to produce these smaller CDs since 20 nominal flashes are removed from the exposure (for this example). The resultant image CD using the same metrics as the 35 nm CD of FIG. 7 is measured to be 32.44 nm with an image spread of 1.414 nm. In this example, a <0.1 nm change to the image spread (which roughly translates to LER) for 2.36 nm image width change from the nominal value is achieved.

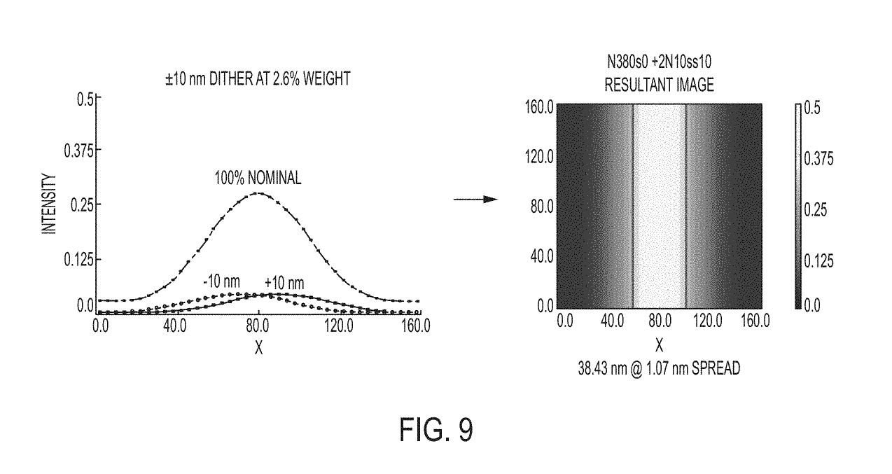

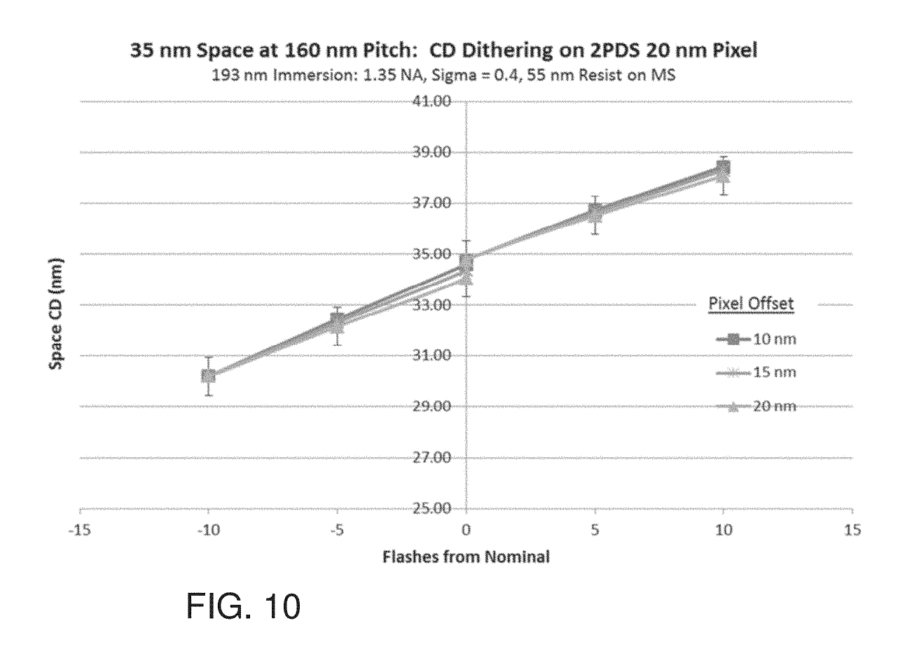

In a similar manner the dithering method disclosed herein can produce features that have CDs less than the nominal target CD. In one example, a target pattern that requires 38.5 nm space is defined. FIG. 9 shows exposure results that use a nominal 380 flashes and the addition of dithered shots that include 10 negative time shifted flashes and 10 positive time shifted flashes. Again, recalling that at the baseline nominal target, i.e. n380s00 (380 flashes, no dithered flashes), 34.8 nm @ 1.27 nm image spread was obtained. In the example of FIG. 9 a smaller image spread (which translates to LER) is achieved for a 3.63 nm image width change and a final image size of 38.43 nm.

The range of CD sizes that can be achieved by dithering the 35 nm target (nominal) space at 160 nm pitch with 20 flashes is shown by the plot in FIG. 9 for dithering values of 10 nm, 15 nm, and 20 nm. A range of 8 nm change is obtained with minimal loss to image fidelity as shown by the error bars in the plot. It should be noted that adding additional dither pulses, larger ±CD changes can be achieved.

As discussed, dither can be accomplished using only pixel shifting as well. For example, a 20 nm shift can corresponds to the same value as the pixel size. This means that no time-shift needs to be added (or subtracted) to the imaging pulses and the features that require CD adjustment can be exposed based on “local shifts” by ±1 pixel to the phase pattern. No change to the pulse timing is required for the imaging system and dithering can be performed for both x (non-scan) and y directions. For a two-dimensional feature, such as a rectangle, dithering using a time-shift to the pulse could only be applied to the direction of the stage scan. Dithering by pixel shift permits both edges to be adjusted since the delay is achieved by the phase shift mirror.

In the examples above, exposures are arranged so that selected line widths can be achieved so as to produce preferred CDs. In other examples, primary and secondary exposures are made so as to adjust or control pattern edges so as to, for example, correct or compensate edge placement error (EPE).

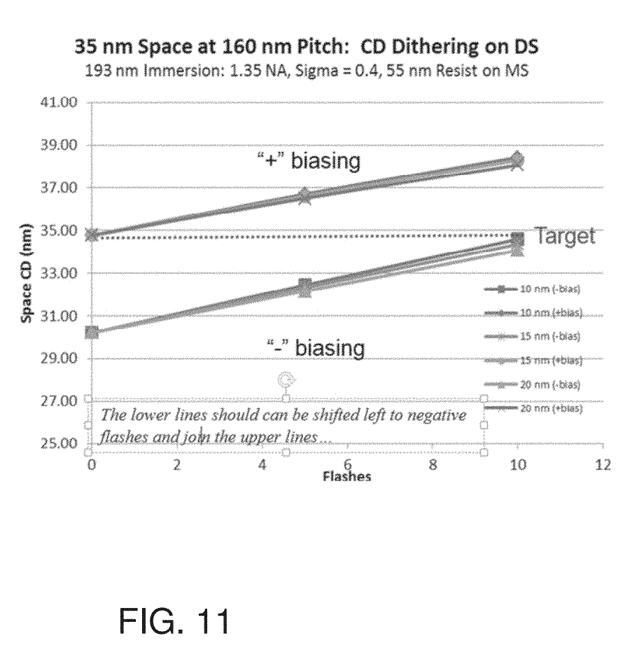

The table below and FIG. 11 illustrate additional arrangements of exposures and resulting image spreads. For these examples, the nominal dose is the dose that provides a 35 nm space without dithering. This is indicated dotted line on the graph of FIG. 11.

Assumes 380 Flashes to achieve Nominal Dose

| | CD at Threshold | | | Image |
|---|---|---|---|---|
| Flash Exposure | 0.295 | 0.3 | 0.305 | Spread (nm) |
| n380s0 | 36.13 | 34.77 | 33.40 | 1.3615 |
| n380s0 + 2n5ss10 | 37.39 | 36.71 | 35.46 | 0.9645 |
| n380s0 + 2n10ss10 | 39.58 | 38.43 | 37.43 | 1.0781 |
| n380s0 + 2n5ss15 | 37.82 | 36.62 | 35.56 | 1.1307 |
| n380s0 + 2n10ss15 | 39.47 | 38.29 | 37.11 | 1.17775 |
| n380s0 + 2n5ss20 | 37.71 | 36.51 | 35.22 | 1.24215 |
| n380s0 + 2n10ss20 | 39.26 | 38.07 | 36.89 | 1.1875 |
| n360s0 | 31.6484 | 30.2031 | 28.7539 | 1.44725 |
| n360s0 + 2n5ss10 | 33.86 | 32.44 | 31.03 | 1.41425 |
| n360s0 + 2n10ss10 | 35.97 | 34.59 | 33.20 | 1.38675 |
| n360s0 + 2n5ss15 | 33.74 | 32.32 | 30.89 | 1.4258 |
| n360s0 + 2n10ss15 | 35.76 | 34.36 | 32.96 | 1.4004 |
| n360s0 + 2n5ss20 | 35.59 | 32.16 | 30.72 | 1.43355 |
| n360s0 + 2n10ss20 | 35.48 | 34.07 | 32.65 | 1.418 |

In addition to the applications described above, dithering can be used in optical proximity correction.

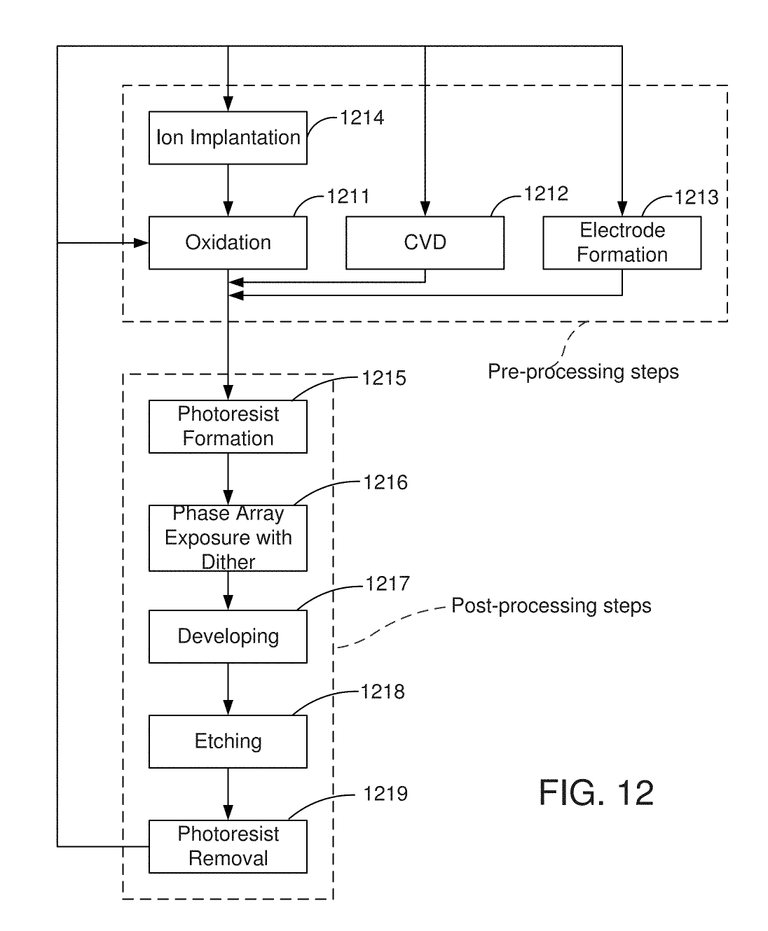

Representative details of a wafer-processing process including a microlithography step are shown in FIG. 12. In step 1211 (“oxidation”) the wafer surface is oxidized. In step 1212 (“CVD”) an insulative layer is formed on the wafer surface by chemical-vapor deposition. In step 1213 (electrode formation) electrodes are formed on the wafer surface by vapor deposition, for example. In step 1214 (“ion implantation”) ions are implanted in the wafer surface. These steps 1211-1214 constitute representative “pre-processing” steps for wafers, and selections are made at each step according to processing requirements.

At each stage of wafer processing, when the pre-processing steps have been completed, the following “post-processing” steps are implemented. A first post-process step is step 1215 (“photoresist formation”) in which a suitable resist is applied to the surface of the wafer. Next, in step 1216 (“exposure”), the dithered exposure systems and methods described above are used for transferring a pattern from the phase array to the resist layer on the wafer. In step 1217 (“developing”) the exposed resist on the wafer is developed to form a usable mask pattern, corresponding to the resist pattern, in the resist on the wafer. In step 1218 (“etching”), regions not covered by developed resist (i.e., exposed material surfaces) are etched away to a controlled depth. In step 1219 (“photoresist removal”), residual developed resist is removed (“stripped”) from the wafer.

Formation of multiple interconnected layers of circuit patterns on the wafer is achieved by repeating the pre-processing and post-processing steps as required. Generally, a set of pre-processing and post-processing steps are conducted to form each layer.

As discussed above, correction or “dither” pixel exposure can be viewed as as a set that moves through the exposure as a pattern portion is exposed. The correction exposures need not be made until nearing the end of the pattern portion exposure, but a number of such exposures can be made during final pattern exposures. Multiple (all) pattern areas are similarly exposed with correction exposures. Such exposures can be visualized as a scrolling screen with information in the pattern to be exposed. Dithered exposures can be associated with the same or different patterns.

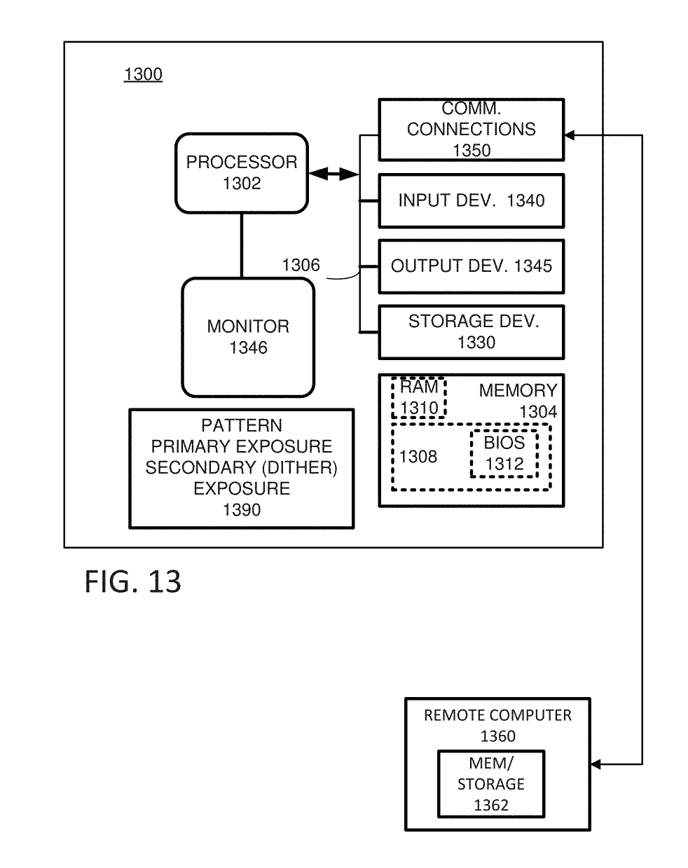

FIG. 13 and the following discussion are intended to provide a brief, general description of an exemplary computing environment in which the disclosed technology may be implemented. Although not required, the disclosed technology is described in the general context of computer-executable instructions, such as program modules, being executed by a personal computer (PC). Generally, program modules include routines, programs, objects, components, data structures, etc., that perform particular tasks or implement particular abstract data types. Moreover, the disclosed technology may be implemented with other computer system configurations, including hand-held devices, multiprocessor systems, microprocessor-based or programmable consumer electronics, network PCs, minicomputers, mainframe computers, and the like. The disclosed technology may also be practiced in distributed computing environments where tasks are performed by remote processing devices that are linked through a communications network. In a distributed computing environment, program modules may be located in both local and remote memory storage devices.

With reference to FIG. 13, an exemplary system for implementing the disclosed technology includes a general purpose computing device in the form of an exemplary conventional PC 1300, including one or more processing units 1302, a system memory 1304, and a system bus 1306 that couples various system components including the system memory 1304 to the one or more processing units 1302. The system bus 1306 may be any of several types of bus structures including a memory bus or memory controller, a peripheral bus, and a local bus using any of a variety of bus architectures. The exemplary system memory 1304 includes read only memory (ROM) 1308 and random access memory (RAM) 1310. A basic input/output system (BIOS) 1312, containing the basic routines that help with the transfer of information between elements within the PC 1300, is stored in ROM 1308. Typically one or more storage devices or a memory such as memory 1390, or a communication connection is coupled to store or communicate pattern definitions and numbers of primary and dither exposures. In cases, photoresist characteristics associated with writing critical dimension features are stored and communicated as well. The memory 1390 can also include computer-executable instructions for dividing a pattern is sets of primary and dithered exposures, and in some examples, these exposures are based on photoresist characteristics so as to achieve a preferred exposure.

The exemplary PC 1300 further includes one or more storage devices 1330 such as a hard disk drive for reading from and writing to a hard disk, a magnetic disk drive for reading from or writing to a removable magnetic disk, and an optical disk drive for reading from or writing to a removable optical disk (such as a CD-ROM or other optical media). Such storage devices can be connected to the system bus 1306 by a hard disk drive interface, a magnetic disk drive interface, and an optical drive interface, respectively. The drives and their associated computer-readable media provide nonvolatile storage of computer-readable instructions, data structures, program modules, and other data for the PC 1300. Other types of computer-readable media which can store data that is accessible by a PC, such as magnetic cassettes, flash memory cards, digital video disks, CDs, DVDs, RAMs, ROMs, and the like, may also be used in the exemplary operating environment.

A number of program modules may be stored in the storage devices 1330 including an operating system, one or more application programs, other program modules, and program data. A user may enter commands and information into the PC 1300 through one or more input devices 1340 such as a keyboard and a pointing device such as a mouse. Other input devices may include a digital camera, microphone, joystick, game pad, satellite dish, scanner, or the like. These and other input devices are often connected to the one or more processing units 1302 through a serial port interface that is coupled to the system bus 1306, but may be connected by other interfaces such as a parallel port, game port, or universal serial bus (USB). A monitor 1346 or other type of display device is also connected to the system bus 1306 via an interface, such as a video adapter. Other peripheral output devices, such as speakers and printers (not shown), may be included.

The PC 1300 may operate in a networked environment using logical connections to one or more remote computers, such as a remote computer 1360. In some examples, one or more network or communication connections 1350 are included. The remote computer 1360 may be another PC, a server, a router, a network PC, or a peer device or other common network node, and typically includes many or all of the elements described above relative to the PC 1300, although only a memory storage device 1362 has been illustrated in FIG. 13. The personal computer 1300 and/or the remote computer 1360 can be connected to a logical a local area network (LAN) and a wide area network (WAN). Such networking environments are commonplace in offices, enterprise-wide computer networks, intranets, and the Internet.

When used in a LAN networking environment, the PC 1300 is connected to the LAN through a network interface. When used in a WAN networking environment, the PC 1300 typically includes a modem or other means for establishing communications over the WAN, such as the Internet. In a networked environment, program modules depicted relative to the personal computer 1300, or portions thereof, may be stored in the remote memory storage device or other locations on the LAN or WAN. The network connections shown are exemplary, and other means of establishing a communications link between the computers may be used.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. I therefore claim as my invention all that comes within the scope and spirit of these claims.

I claim:

1. An exposure method for exposing an object with exposure light via a plurality of pattern elements situated at a pattern surface, the method comprising:
exposing a first exposure region on the object with a first exposure light received from pattern elements from the plurality of optical elements positioned in a first region of the pattern surface; and
exposing a second exposure region which partially overlaps the first exposure region on the object with a second exposure light with a plurality of optical elements from the plurality of optical elements positioned in a second region of the pattern surface which partially overlaps the first region of the pattern surface.

2. The method of claim 1, further comprising
exposing a third exposure region on the object which partially overlaps the first exposure region on the object and which is different from the second exposure region in the object, with a third exposure light from optical elements from the plurality of optical elements positioned in a third region which partially overlaps the first region and which is different from the second region.

3. The method of claim 2, wherein the second exposure region is located on a first side with respect to the first exposure region, and the third exposure region is located on a second side opposite the first side with respect to the first exposure region.

4. The method of claim 2, wherein an energy amount of the first exposure light is larger than a sum of an energy amount of the second exposure light and an energy amount of the third exposure light.

5. The method of claim 1, wherein an energy amount of the first exposure light is larger than an energy amount of the second exposure light.

6. The method of claim 1, further comprising
exposing a third exposure region which is adjacent to the first exposure region on the object with a third exposure light having a phase difference with respect to the first exposure light, the third exposure light received from a third region of the pattern which is adjacent to the first region of the pattern surface.

7. The method of claim 6, further comprising
exposing a fourth exposure region which is adjacent to the second exposure region on the object by a fourth exposure light having a phase difference with respect to the second exposure light, the fourth exposure light received from fourth region of the pattern surface which is adjacent to the second region on the pattern surface.

8. The method of claim 1, wherein the exposure light is pulsed light.

9. The method of claim 8, wherein a number of pulses of the first exposure light is larger than a number of pulses of the second exposure light.

10. The method of claim 1, wherein the exposing is performed while changing a positional relationship between the exposure light and the object.

11. A device manufacturing method comprising:
forming a pattern in a photosensitive layer on a substrate by exposing the photosensitive layer according to the method of claim 1; and
processing the substrate with the patterned photosensitive layer.

12. An exposure apparatus for exposing an object with exposure light from a light source, the apparatus comprising:
a spatial light modulator including a plurality of optical elements arranged in an optical path of the exposure light; and
a controller configured to control the spatial light modulator so as to selectively set selected optical elements of the plurality of optical elements in a first state or a second state, wherein the controller controls the spatial light modulator so as to:
expose a first exposure region on the object with a first exposure light from optical elements positioned in a first region of the spatial light modulator selected from the plurality of optical elements; and
expose a second exposure region on the object which partially overlaps the first exposure region on the object with a second exposure light from optical elements of the plurality of optical elements positioned in a second region of the spatial light modulator, wherein the second region of the spatial light modulator partially overlaps the first region of the spatial light modulator.

13. The apparatus of claim 12, wherein the controller controls the spatial light modulator so as to expose a third exposure region which partially overlaps the first exposure region and which is different from the second exposure region, on the object by a third exposure light from optical elements positioned in a third region which is partially overlapped the first region and which is different from the second region, from the plurality of optical elements.

14. The apparatus of claim 13, wherein the second exposure region is located on a first side with respect to the first exposure region, and the third exposure region is located on a second side opposite the first side with respect to the first exposure region.

15. The apparatus of claim 14, wherein an energy amount of the first exposure light is larger than a sum of an energy amount of the second exposure light and an energy amount of the third exposure light.

16. The apparatus of claim 12, wherein an energy amount of the first exposure light is larger than an energy amount of the second exposure light.

17. The apparatus of claim 12, wherein the controller controls the spatial light modulator so as to expose a third exposure region which is adjacent to the first exposure region on the object by a third exposure light having a phase difference with respect to the first exposure light, the third exposure light come from a third region which is adjacent to the first region on the arrange surface.

18. The apparatus of claim 17, wherein the controller controls the spatial light modulator so as to expose a fourth exposure region which is adjacent to the second exposure region on the object by a fourth exposure light having a phase difference with respect to the second exposure light, the fourth exposure light coming from a fourth region which is adjacent to the second region on the arrange surface.

19. The apparatus of claim 12, wherein the light source supplies pulsed light.

20. The apparatus of claim 19, wherein a number of pulses of the first exposure light is larger than a number of pulses of the second exposure light.

21. The apparatus of claim 12, exposing the object during changing relationship between the exposure light and the object.

22. The apparatus of claim 12, wherein the plurality of optical elements includes a reflective element which is movable in a vertical direction respectively.

23. A device manufacturing method comprising:
forming pattern of photosensitive layer on a substrate by using exposure apparatus of claim 12; and
processing the patterned substrate.
